(19) United States
(12) Patent Application Publication
(10) Pub. No.: US 2012/0100785 A1
(43) Pub. Date: Apr. 26, 2012

(54) METHOD FOR CHAMFERING WAFER

(75) Inventors: Yukio Ishimasa, Tokyo (JP); Ichiro Katayama, Tokyo (JP); Tadahiro Kato, Fukushima (JP); Kuniaki Oonishi, Fukushima (JP)

(73) Assignees: SHIN-ETSU HANDOTAI CO., LTD., Tokyo (JP); DAITO ELECTRON CO., LTD., Osaka-shi, Osaka (JP)

(21) Appl. No.: 13/264,635

(22) PCT Filed: Mar. 30, 2010
(86) PCT No.: PCT/JP2010/055683

§ 371 Date: Dec. 22, 2011

(30) Foreign Application Priority Data
Apr. 15, 2009 (JP) 2009-099410

(51) Int. Cl. B24B 1/00

(52) U.S. Cl. 451/41

(57) ABSTRACT

In a conventional wafer chamfering process, the chamfered shape (cross-sectional shape) of the wafer circumference is uniform. However, in the chamfering step in wafer manufacture, the uniform chamfered shape varies with respective circumferential positions. Therefore, a wafer chamfering method that takes into account deformation in the chamfering step in the wafer manufacture is to be provided. The wafer chamfering method is for chamfering a wafer by bringing a grooveless grindstone into contact with the edge (circumferential end) of a wafer. By this wafer chamfering method, a movement trajectory formed by moving the wafer and the grindstone in a relative manner in the Z-axis and Y-axis directions and forming the same cross-sectional shape on the entire wafer circumference is set as a reference. So as to perform a processing operation in which the relative positions of the wafer and the grindstone are changed from positions on the reference trajectory at least in one of the Z-axis and Y-axis directions depending on wafer rotation angle positions, different cross-sectional shapes are formed depending on the wafer rotation angle positions with the use of a piezoelectric actuator.

### TECHNICAL FIELD

The present invention relates to processing methods by which chamfered shapes are varied in the wafer circumferential direction and thickness direction in the step of chamfering a wafer with grooveless rotative grindstones.

### BACKGROUND ART

In a process for chamfering a disk-like thin plate to be used as an integrated circuit substrate such as one of various crystal wafers or one of other semiconductor device wafers, or a disk-like thin plate made of a hard material containing some other metal material, such as a silicon (Si) single crystal, gallium arsenic (GaAs), crystalline quartz, quartz, sapphire, ferrite, or silicon carbide (SiC) (any of the above will be referred to simply as a wafer), grinding is performed with the use of a crude-grinding grindstone formed by hardening industrial diamond introduced as abrasive grains thereinto with a resin binder, and polishing is then performed with the use of colloidal silica for finishing. In this manner, a circumferential edge portion having a predetermined shape and predetermined surface roughness is formed.

A wafer 1 to be used in such a chamfering process has a V-shaped or U-shaped notch 1n indicating the reference position in the circumferential direction, as shown in FIG. 1.

In some cases, as shown in FIG. 2, an edge (circumferential end portion) 1a of the wafer 1 may be processed into a cross-sectional shape (substantially a triangular shape as a whole) having an upper slope 1au tilted at an angle α1 (approximately 22 degrees) with respect to an upper flat surface 1su, a lower slope 1ad tilted at the angle α1 (approximately 22 degrees) with respect to a lower flat surface 1sd, and a single circular arc 1c that has a radius R1 and smoothly connects the upper and lower slopes to each other.

In this case, the horizontal length of the upper slope 1au is referred to as the “chamfer width X1”, and the horizontal length of the lower slope 1ad is referred to as the “chamfer width X2”.

Also, as shown in FIG. 3, the edge 1a of the wafer 1 may be processed into a cross-sectional shape (a trapezoidal shape) having an upper slope 1au tilted at an angle α2 with respect to the upper flat surface 1su, a lower slope 1ad tilted at the angle α2 with respect to the lower flat surface 1sd, and two circular arcs 1c, 1c that have the same radius R2 and smoothly connect the upper and lower slopes to a circumferential end 1b forming the end face of the edge 1a.

In this case, the horizontal length of the upper slope 1au is referred to as the “chamfer width X1”, the horizontal length of the lower slope 1ad is referred to as the “chamfer width X2”, and the length of the surface of the circumferential end 1b is referred to as the “chamfer width X3”.

In some of such wafer chamfering processes, processing is performed with the use of a profile grindstone having grooves for forming the outer shape of the wafer circumferential end portion to be processed, so as to obtain a cross-sectional shape and achieve a cross-sectional shape accuracy (Patent Documents 1, 2).

In a case where a profile grindstone is used, however, cooling agents do not easily enter the deepest portions of the grooves in the grindstone. Therefore, the grindstone is easily damaged, and grinding marks remain in the circumferential direction of the edge. As a result, the surface roughness tends to become higher.

To counter this problem, a polishing method and apparatus using a rubber wheel containing a polishing agent as the grindstone for chamfering wafers have been suggested. Particularly, where a rubber wheel having a large diameter is used, grinding marks can be made even smaller (Patent Document 3).

However, even when polishing is performed in such a manner that the center of the rotary shaft to which the rubber wheel is secured becomes parallel to the direction of rotation of the wafer, two or three pits remain in the entire circumference of the edge, and such pits are not completely eliminated in the entire circumference.

In view of this, there has been a suggested processing method by which polishing is performed after calculating the required inclination angle α of the rotary shaft of the rubber wheel from the circumferential velocity of the rubber wheel and the circumferential velocity of the wafer so that the polishing direction at the edge is at approximately 45 degrees with respect to the planar direction, and tilting the rotary shaft at the required inclination angle (Patent Document 4).

Also, there has been a processing method by which two disk-like grooveless grindstones are placed in the vicinity of the same point in the wafer circumferential end portion of a rotating wafer, and are positioned to face each other. Regions close to the same point in the wafer circumferential end portion are simultaneously processed and molded with the processing surfaces of the rotating grooveless grindstones (Patent Document 5).

### PRIOR ART DOCUMENT

### Patent Documents

Patent Document 1: Japanese Patent Application Laid-Open (JP-A) No. 06-262505

Patent Document 2: JP-A No. 11-207584

Patent Document 3: JP-A No. 2000-052210

Patent Document 4: JP-A No. 2005-040877

Patent Document 5: JP-A No. 2008-177348

### Problems in Conventional Arts

It has become apparent that, by those conventional methods for chamfering wafers, the chamfered shape (cross-sectional shape) of the circumference of a wafer is uniform, but the uniform chamfered shape varies with respective circumferential positions in the post processing in the wafer manufacture.

Also, as the degree of integration of semiconductor chips becomes higher, the density of integrated circuits to be formed on the wafer 1 also becomes higher. The circuit area in the wafer 1 also expands to the circumferential edge portion, and the areas in the edge 1a without circuits formed therein are reduced, and the circuit formation area almost reaches the circumferential end edge. In this manner, the wafer 1 is more efficiently used, and a waste of the end edge portion and the proportion of the waste in the end edge portion are required to be minimized. Therefore, the end edge shape needs to be made smaller, and the processing accuracy in forming symmetrical shapes in the thickness direction needs to be made higher. As a result, there is a demand for development of a novel processing method to satisfy the above requirements.

### DISCLOSURE OF THE INVENTION

### Problems to be Solved by the Invention

The present invention has been made in view of the above problems in the conventional arts, and, to solve those problems, the technical objective thereof is to provide a wafer chamfering method for accurately forming required cross-sectional shapes with higher cross-sectional shape precision in a wafer chamfering process, to cope with the post processing in the wafer manufacture.

### Means to Solve the Problems

The means to solve the above problems by a wafer chamfering method according to the present invention are as follows.

First means to solve the problems by a wafer chamfering method is a wafer chamfering method for chamfering a wafer by performing centering of a wafer, placing the wafer on a rotary table, rotating the wafer, and bringing a grooveless grindstone into contact with a wafer circumferential end portion (an edge), the grooveless grindstone being for processing the rotating wafer.

This wafer chamfering method characteristically includes: setting a reference movement trajectory that is formed by moving the wafer and the grindstone in a relative manner in the Z-axis and Y-axis directions, and forming the same cross-sectional shape on the entire wafer circumference; and forming different cross-sectional shapes depending on wafer rotation angle positions with the use of a piezoelectric actuator, so as to perform a processing operation in which the relative positions of the wafer and the grindstone are changed from positions on the reference trajectory in at least one of the Z-axis and Y-axis directions, depending on the wafer rotation angle positions.

In second means to solve the problems by the wafer chamfering method, a relative positional relationship between the grindstone and the wafer is alternately changed at every 45 degrees in rotation angle of the wafer, to form two different cross-sectional shapes.

In third means to solve the problems by the wafer chamfering method, a wafer cross-sectional shape is continuously varied in rotation angle positions between changes in the relative positional relationship between the grindstone and the wafer at every 45 degrees in rotation angle of the wafer.

In fourth means to solve the problems by the wafer chamfering method, a relative positional relationship between the grindstone and the wafer is alternately changed at every 45 degrees in rotation angle of the wafer, to form two different wafer radiuses.

In fifth means to solve the problems by the wafer chamfering method, a wafer radius is continuously varied in rotation angle positions between changes in the relative positional relationship between the grindstone and the wafer at every 45 degrees in rotation angle of the wafer.

In sixth means to solve the problems by the wafer chamfering method, the two cross-sectional shapes have different circular arc sizes at a wafer edge while maintaining the same chamfer width of a wafer edge slope.

In seventh means to solve the problems by the wafer chamfering method, the two cross-sectional shapes have different curved lines at a wafer edge while maintaining the same chamfer width of a wafer edge slope and the same straight line length at the wafer edge portion.

In eighth means to solve the problems by the wafer chamfering method, the two cross-sectional shapes have a wafer edge slope at different angels while maintaining the same chamfer width of the wafer edge slope.

In ninth means to solve the problems by the wafer chamfering method, a trajectory is set by moving the wafer and the grindstone in a relative manner in the Z-axis and Y-axis directions, and bringing the grindstone into contact with the wafer to form a desired cross-sectional shape at a wafer edge,

a circular-arc or curved-line start position adjacent to a straight line portion at the wafer edge is deviated from the trajectory by a predetermined amount, and

processing is performed by gradually returning to an original circular-arc or curved-line trajectory as the wafer edge becomes further away.

In tenth means to solve the problems by the wafer chamfering method, the amount of deviation of the circular-arc or curved-line start position adjacent to the straight line portion at the wafer edge varies with wafer rotation angles.

In eleventh means to solve the problems by the wafer chamfering method, after a desired cross-sectional shape is formed at a wafer edge by moving the wafer and the grindstone in a relative manner in the Z-axis and Y-axis directions,

the grindstone is again brought into contact with a straight line portion at the wafer edge, and is moved in a relative manner in the Z-axis and Y-axis directions, processing being performed by tilting the straight line portion at the wafer edge at a predetermined angle with respect to an original straight line.

Twelfth means to solve the problems by the wafer chamfering method is a wafer chamfering method for chamfering a wafer by performing centering of a wafer, placing the wafer on a rotary table, rotating the wafer, and bringing a grooveless grindstone into contact with a wafer circumferential end portion, the grooveless grindstone being for processing the rotating wafer,

the wafer chamfering method including:

setting a trajectory by moving the wafer and the grindstone in a relative manner in Z-axis and Y-axis directions, and bringing the grindstone into contact with the wafer to form the same cross-sectional shape at an edge on an entire wafer circumference,

deviating a circular-arc or curved-line start position adjacent to a straight line portion at the wafer edge from the trajectory by a predetermined amount, and

performing processing by gradually returning to an original circular-arc or curved-line trajectory as the wafer edge becomes further away.

Thirteenth means to solve the problems by the wafer chamfering method is a wafer chamfering method for chamfering a wafer by performing centering of a wafer, placing the wafer on a rotary table, rotating the wafer, and bringing a grooveless grindstone into contact with a wafer circumferential end portion, the grooveless grindstone being for processing the rotating wafer,

the wafer chamfering method including:

forming the same cross-sectional shape at an edge on an entire wafer circumference by moving the wafer and the grindstone in a relative manner in Z-axis and Y-axis directions; and

performing processing by again bringing the grindstone into contact with a straight line portion at the wafer edge, moving the grindstone in a relative manner in the Z-axis and Y-axis directions, and tilting the straight line portion at the wafer edge at a predetermined angle with respect to an original straight line.

In fourteenth means to solve the problems by a wafer chamfering method, a cross-section of the wafer is measured in a projected image; and movements of the grindstone and the wafer in the Z-axis and Y-axis directions are determined so that the wafer edge has a desired cross-sectional shape.

### Effect of the Invention

A first means to solve the above problems by a wafer chamfering method provides a wafer chamfering method for chamfering a wafer by performing centering of a wafer, placing the wafer on a rotary table, rotating the wafer, and bringing a grooveless grindstone into contact with a wafer circumferential end portion, the grooveless grindstone being for processing the rotating wafer.

This wafer chamfering method characteristically includes: setting a reference movement trajectory that is formed by moving the wafer and the grindstone in a relative manner in the Z-axis and Y-axis directions, and forming the same cross-sectional shape on the entire wafer circumference; and forming different cross-sectional shapes depending on wafer rotation angle positions with the use of a piezoelectric actuator, so as to perform a processing operation in which the relative positions of the wafer and the grindstone are changed from positions on the reference trajectory in at least one of the Z-axis and Y-axis directions, depending on the wafer rotation angle positions.

Chamfering is performed on a wafer after correcting beforehand the changes to be caused in the chamfered cross-sectional shape and the wafer during the post processing (chemical processing, mechanical processing) after the chamfering step in a wafer manufacturing process and a process for manufacturing semiconductor devices on the surface of the wafer. Accordingly, the cross-section and radius shape of the wafer edge can be accurately formed into a desired shape at last, and the surface flatness after the post processing and the semiconductor device yield can be made higher. Also, based on the reference trajectory positions, the positions and amounts of relative movements of the wafer and the grindstone can be easily determined. As a result, different cross-sectional shapes can be easily formed, depending on the wafer rotation angle positions.

Further, a piezoelectric actuator is used for an operation to perform processing, with the grindstone being deviated from the reference trajectory position. Accordingly, the processing can be accurately followed particularly in the wafer chamfering process of the present invention by which the cross-sectional shape is varied depending on rotation angle positions of the wafer 1 rotating at a high speed.

In a second means to solve the problems by the wafer chamfering method, the relative positional relationship between the grindstone and the wafer is alternately changed at every 45 degrees in rotation angle of the wafer, to form two different cross-sectional shapes. Accordingly, it is possible to cope with the inhomogeneity appearing in eight directions due to the crystalline structure of the wafer.

That is, silicon single crystals or compound semiconductor crystals forms two kinds of crystal planes that differ in chemical and mechanical properties at every 45 degrees about the center of the wafer, because of the panes of diamond structure crystals. There are continuous changes between the two kinds of crystal planes, but a method for correcting those changes can be achieved.

In a third means to solve the problems by the wafer chamfering method, the wafer cross-sectional shape is continuously varied in rotation angle positions between changes in the relative positional relationship between the grindstone and the wafer at every 45 degrees in rotation angle of the wafer. Accordingly, in coping with the shape inhomogeneity appearing in the eight directions due to the crystalline structure of the wafer, the changes in the shape in those changing positions can be made smooth.

In a fourth means to solve the problems by the wafer chamfering method, the relative positional relationship between the grindstone and the wafer is alternately changed at every 45 degrees in rotation angle of the wafer, to form two different wafer radiuses. Accordingly, it is possible to cope with the shape inhomogeneity appearing in the eight directions due to the crystalline structure of the wafer.

In a fifth means to solve the problems by the wafer chamfering method, the wafer radius is continuously varied in rotation angle positions between changes in the relative positional relationship between the grindstone and the wafer at every 45 degrees in rotation angle of the wafer. Accordingly, in coping with the shape inhomogeneity appearing in the eight directions due to the crystalline structure of the wafer, the changes in the radius in those changing positions can be made smooth.

In a sixth means to solve the problems by the wafer chamfering method, the two cross-sectional shapes have different circular arc sizes at the wafer edge while maintaining the same chamfer width of a wafer edge slope. Accordingly, it is possible to cope with the edge shape inhomogeneity appearing due to the crystalline structure of the wafer.

In a seventh means to solve the problems by the wafer chamfering method, the two cross-sectional shapes have different curved lines at the wafer edge while maintaining the same chamfer width of a wafer edge slope and the same straight line length at the wafer edge. Accordingly, it is possible to cope with the edge shape inhomogeneity appearing due to the crystalline structure of the wafer.

In an eighth means to solve the problems by the wafer chamfering method, the two cross-sectional shapes have a wafer edge slope at different angles while maintaining the same chamfer width of the wafer edge slope. Accordingly, it is possible to cope with the edge shape inhomogeneity appearing due to the crystalline structure of the wafer.

In a ninth means to solve the problems by the wafer chamfering method, a trajectory is set by moving the wafer and the grindstone in a relative manner in the Z-axis and Y-axis directions, and bringing the grindstone into contact with the wafer to form a desired cross-sectional shape at the wafer edge. A circular-arc or curved-line start position adjacent to the straight line portion at the wafer edge is deviated from the trajectory by a predetermined amount, and processing is performed by gradually returning to the original circular-arc or curved-line trajectory as the wafer edge becomes further away. To cope with a situation where a wafer cross-sectional shape cannot be processed into a desired shape due to mechanical strain and deformation appearing in the apparatus or the wafer during the wafer chamfering step or due to a shape asymmetrical in the wafer thickness direction in particular, those distortions are taken into account beforehand informing the cross-sectional shape. Accordingly, a desired cross-sectional shape (such as a shape symmetrical in the wafer thickness direction) can be formed as a result of the post processing, and the post processing precision and yield (such as the surface flatness and the semiconductor device yield) can be made higher.

In a tenth means to solve the problems by the wafer chamfering method, the amount of deviation of the circular-arc or curved-line start position adjacent to the straight line portion at the wafer edge varies with wafer rotation angles. Accordingly, it is possible to cope with the edge shape inhomogeneity appearing depending on rotation angles due to the crystalline structure of the wafer.

In an eleventh means to solve the problems by the wafer chamfering method, after a desired cross-sectional shape is formed at the wafer edge by moving the wafer and the grindstone in a relative manner in the Z-axis and Y-axis directions, the grindstone is again brought into contact with the straight line portion at the wafer edge, and is moved in a relative manner in the Z-axis and Y-axis directions, processing being performed by tilting the straight line portion at the wafer edge at a predetermined angle with respect to an original straight line. To cope with a situation where a wafer cross-sectional shape cannot be processed into a desired shape due to mechanical strain and deformation appearing in the apparatus or the wafer during the wafer chamfering step or due to a shape asymmetrical in the wafer thickness direction in particular, those distortions are taken into account beforehand in forming the cross-sectional shape. Accordingly, a desired cross-sectional shape (such as a shape symmetrical in the wafer thickness direction) can be formed as a result of the post processing, and the post processing precision and yield (such as the surface flatness and the semiconductor device yield) can be made higher.

In a twelfth means to solve the problems by the wafer chamfering method, a trajectory is set by moving the wafer and the grindstone in a relative manner in the Z-axis and Y-axis directions, and bringing the grindstone into contact with the wafer to form the same cross-sectional shape at the edge on the entire wafer circumference.

A circular-arc or curved-line start position adjacent to the straight line portion at the wafer edge is deviated from the trajectory by a predetermined amount, and processing is performed by gradually returning to the original circular-arc or curved-line trajectory as the wafer edge becomes further away.

To cope with a situation where a wafer cross-sectional shape cannot be processed into a desired shape due to mechanical strain and deformation appearing in the apparatus or the wafer during the wafer chamfering step or due to a shape asymmetrical in the wafer thickness direction in particular, those distortions are taken into account beforehand in forming the cross-sectional shape. Accordingly, a desired cross-sectional shape (such as a shape symmetrical in the wafer thickness direction) can be formed as a result of the post processing, and the post processing precision and yield (such as the surface flatness and the semiconductor device yield) can be made higher.

In a thirteenth means to solve the problems by the wafer chamfering method, the same cross-sectional shape is formed at the edge on the entire wafer circumference by moving the wafer and the grindstone in a relative manner in the Z-axis and Y-axis directions. After that, processing is performed by again bringing the grindstone into contact with the straight line portion at the wafer edge, moving the grindstone in a relative manner in the Z-axis and Y-axis directions, and tilting the straight line portion at the wafer edge at a predetermined angle with respect to the original straight line.

To cope with a situation where a wafer cross-sectional shape cannot be processed into a desired shape due to mechanical strain and deformation appearing in the apparatus or the wafer during the wafer chamfering step or due to a shape asymmetrical in the wafer thickness direction in particular, those distortions are taken into account beforehand in forming the cross-sectional shape. Accordingly, a desired cross-sectional shape (such as a shape symmetrical in the wafer thickness direction) can be formed as a result of the post processing, and the post processing precision and yield (such as the surface flatness and the semiconductor device yield) can be made higher.

In a fourteenth means to solve the problems by the wafer chamfering method, cross-sections of the wafer are measured in projected images, and movements of the grindstone and the wafer in the Z-axis and Y-axis directions are determined so that the wafer edge has a desired cross-sectional shape. Accordingly, cross-sectional shapes can be advantageously measured, even though the wafer is not broken. Also, since the projected images are in a non-contact state, the measurement time is short, and the measurement can be carried out without leaving any scar to the wafer.

### BRIEF DESCRIPTION OF THE DRAWINGS

FIG. 1 is an explanatory perspective view illustrating a processed state of a wafer circumferential end in a first embodiment according to a processing method of the present invention.

FIG. 2 is an explanatory partially-enlarged cross-sectional view illustrating a contact state between a wafer circumferential end and disk-like grooveless grindstones in the first embodiment.

FIG. 3 is an explanatory partially-enlarged cross-sectional view illustrating a contact state between a wafer circumferential end having a different shape from that of FIG. 2 and the disk-like grooveless grindstones in the first embodiment.

FIG. 4 is an explanatory partially-enlarged cross-sectional view illustrating a contact state of the disk-like grooveless grindstones in a contouring process in the first embodiment.

FIG. 5 is an explanatory partially-enlarged cross-sectional view illustrating a state of the disk-like grooveless grindstones having positions varied with misalignment of the wafer position in the contouring process in the first embodiment.

FIG. 6 is a diagram for explaining processing and showing oblique grinding marks formed by the disk-like grooveless grindstones in the first embodiment.

FIG. 7 is a front view of a processing apparatus to be used in the present invention.

FIG. 8 is a side view of the processing apparatus to be used in the present invention.

FIG. 9 is a plan view of the processing apparatus to be used in the present invention.

FIG. 10 is a diagram showing the control system of the processing apparatus to be used in the present invention.

FIG. 11 is a block diagram showing part of the control system of the processing apparatus to be used in the present invention.

FIG. 12 is a diagram for explaining the processing and showing the trajectory of the grindstone processing the upper face side of the wafer circumferential end.

FIG. 13 is a diagram for explaining the processing and showing the trajectory of the grindstone processing the lower face side of the wafer circumferential end.

FIG. 14 is an explanatory plan view of a conventionally-used wafer with a notch.

FIG. 15 is an explanatory plan view of a notched wafer formed into a first cross-sectional shape in the first embodiment.

FIG. 16 is a partial cross-sectional view of a wafer end portion having an edge shape formed with a vertical circumferential face having two circular arcs at the corner portions at the edge.

FIG. 17 is a partial cross-sectional view of a wafer end portion having an edge shape processed to have larger circular arcs at the corner portions than those of FIG. 16.

FIG. 18 is a partial cross-sectional view of a wafer end portion having an edge shape processed to have smaller circular arcs at the corner portions than those of FIG. 16.

FIG. 19 is a partial cross-sectional view of a wafer end portion having an edge shape processed to have gentler curves at the corner portions than those of FIG. 16.

FIG. 20 is a partial cross-sectional view of a wafer end portion having an edge shape processed to have tighter curves at the corner portions than those of FIG. 16.

FIG. 21 is a partial cross-sectional view of a wafer end portion having an edge shape processed to have the wafer edge slopes at larger angles than those of FIG. 16.

FIG. 22 is a partial cross-sectional view of a wafer end portion having an edge shape processed to have the wafer edge slopes at smaller angles than those of FIG. 16.

FIG. 23 is a partial cross-sectional view of a wafer end portion formed by shifting, by a predetermined amount, the circular-arc or curved-line start positions adjacent to the straight line portion at the wafer edge.

FIG. 24 is a partial cross-sectional view of a wafer having no deformation during the chamfering step.

FIG. 25 is a partial cross-sectional view illustrating deformation of a wafer during the chamfering step.

FIG. 26 is a partial cross-sectional view illustrating a situation where the wafer recovers from the deformation after the chamfering step.

FIG. 27 is a cross-sectional view of a, wafer processed by tilting the straight line portion at the wafer edge at a predetermined angle with respect to the original straight line.

FIG. 28 is a perspective view illustrating a wafer chamfering method according to a fourth embodiment by which projected images are used for measurement.

### BEST MODE FOR CARRYING OUT THE INVENTION

A general wafer chamfering method using disk-like grooveless grindstones is described.

By a wafer chamfering method, outer circumferential surfaces of disk-like grooveless grindstones 3, 3 are brought into contact with a wafer 1, and the two disk-like grindstones 3, 3 in contact with the single wafer 1 simultaneously perform a chamfering operation.

The wafer 1 is placed concentrically on a rotary table, 2a (see FIG. 4) provided on a work table 2, and the two disk-like grooveless grinds tones 3, 3 perform a chamfering operation simultaneously on the wafer 1 rotating with the rotary table 2a.

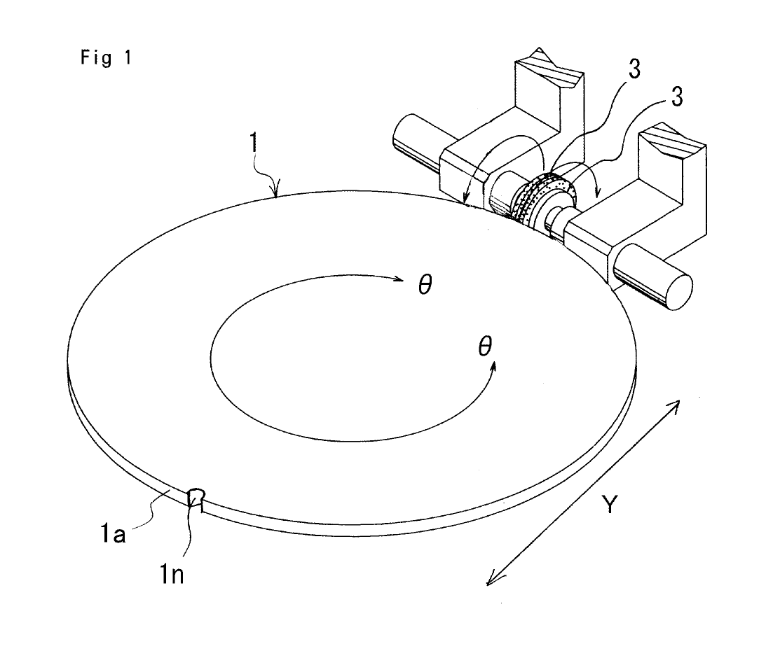

The two disk-like grooveless grindstones 3, 3 arc located near the same point at a circumferential end 1b, and the side faces facing each other are located in the vicinity of each other The circumferential surfaces of the two rotating grooveless grindstones 3, 3 are simultaneously brought as processing surfaces into contact with the wafer 1, and the portions of an edge (a circumferential end portion of the wafer 1) 1a close to each other are simultaneously processed and molded (see FIGS. 1, 2, and 4).

The two grooveless grindstones 3, 3 perform processing by setting the rotation directions of the respective grooveless grindstones 3, 3 so that the processing directions at the point of contact with the wafer 1 are the opposite directions from each other.

The respective grindstones 3, 3 may move in the same direction at the same time or move in different directions from each other and independently from each other, depending on the type of processing and the shape of the end portion of the wafer 1 to be processed.

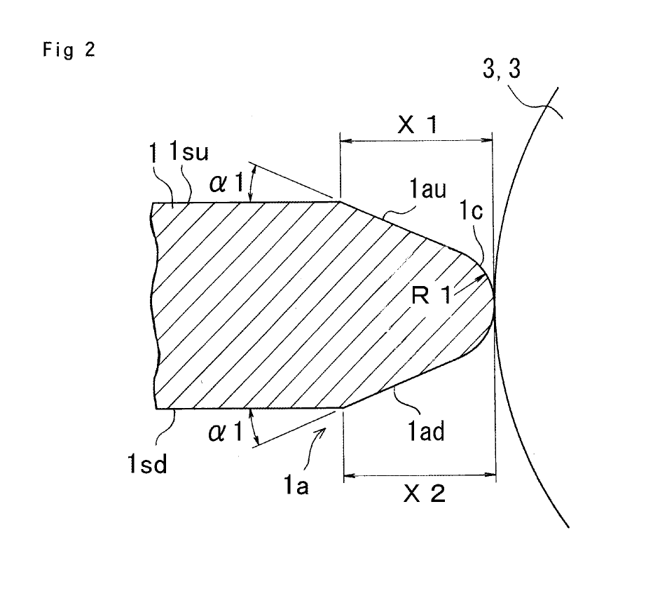

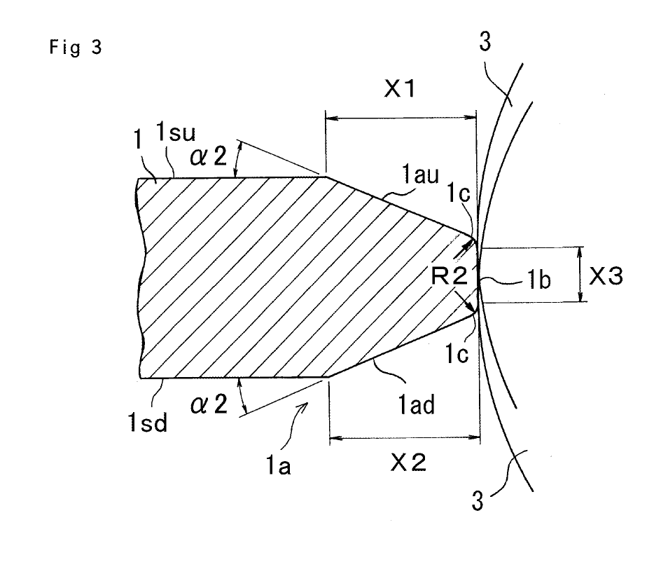

In a case where the wafer 1 having a notch 1n is to be processed (see FIG. 1), in a circumferential-end diameter reducing process for reducing the diameter by grinding the outside diameter of the wafer 1, the two grooveless grindstones 3, 3 are brought into contact with the wafer 1 and process the wafer 1 while being maintained at predetermined heights (see FIGS. 2 and 3).

In a case where the wafer 1 to be processed has the edge 1a having a cross-sectional shape formed with upper and lower slopes 1au and 1ad, the circumferential end 1b, and a circular arc 1c of the radius R1 (a cross-sectional triangular shape), processing is performed while the two disk-shaped grooveless grindstones 3, 3 are maintained at the same height (see FIG. 2).

In a case where the wafer 1 to be processed has the edge 1a having a cross-sectional shape formed with upper and lower slopes 1au and 1ad, the circumferential end 1b forming a vertical face, and circular arcs 1c, 1c connected to the upper and lower corner portions having the same radiuses R2 between the slopes and the circumferential end (a cross-sectional trapezoidal shape), the two disk-like grooveless grindstones 3, 3 are positioned at different heights from each other so that the circumferential end 1b is processed as a substantially vertical face. While the disk-like grooveless grindstones 3, 3 are maintained in the above positions, the circumferential end is processed by rotating the wafer 1 (see FIG. 3).

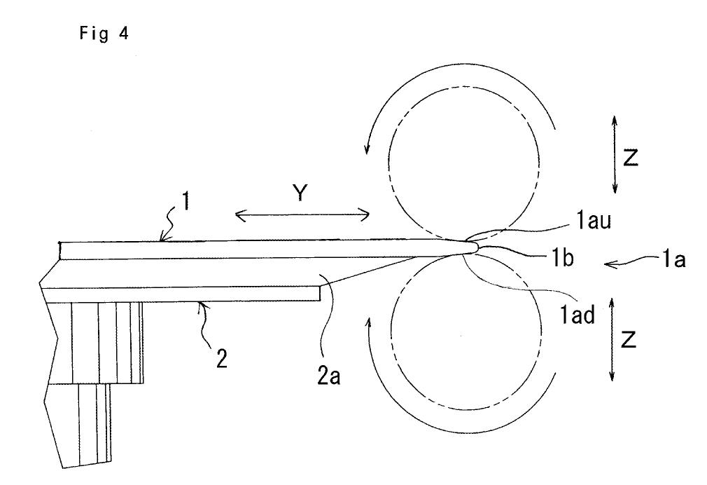

In a contouring process for forming the cross-section of the edge 1a into a desired shape, the two grooveless grindstones 3, 3 are moved independently of each other along the respective faces of the edge 1a, and the same portion of the edge 1a in the radial direction is sandwiched by the grooveless grindstones 3, 3 from above and below. The respective faces are then processed at the same time (see FIGS. 4 and 5).

In a case where the cross-sectional shape of the edge 1a is vertically symmetrical in the contouring process, the two disk-like grooveless grindstones 3, 3 are operated independently of each other. When one of the grindstones 3, 3 processes the upper side of the wafer 1, the other one processes the lower side of the wafer 1. While restraining the wafer 1 from flipping or moving up and down, the grindstones 3, 3 process the cross-sectional shape of the edge 1a (see FIGS. 4 and 5).

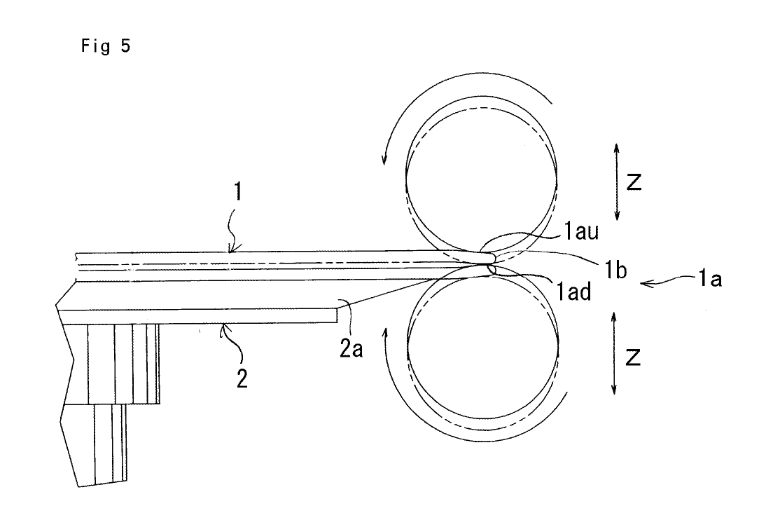

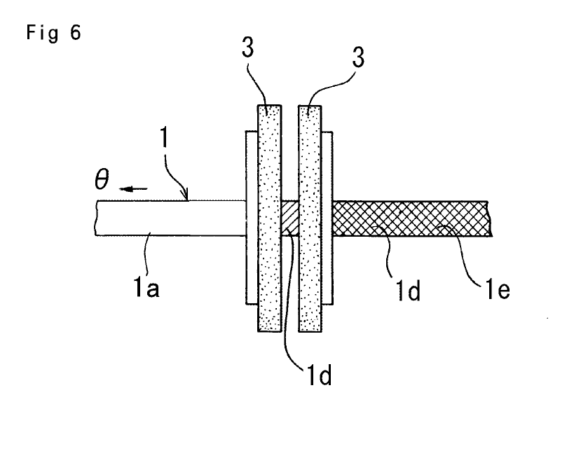

It should be noted that, by making the directions of rotation of the two grooveless grindstones 3, 3 simultaneously in contact with the point of contact with the wafer 1 opposite from each other, the wafer 1 can be restrained from flipping, and oblique grinding marks 1d and 1e in the processing intersect with each other so that the processed faces can have lower surface roughness and become finer. Accordingly, the processing accuracy of the cross-sectional shape can be made higher (FIG. 6).

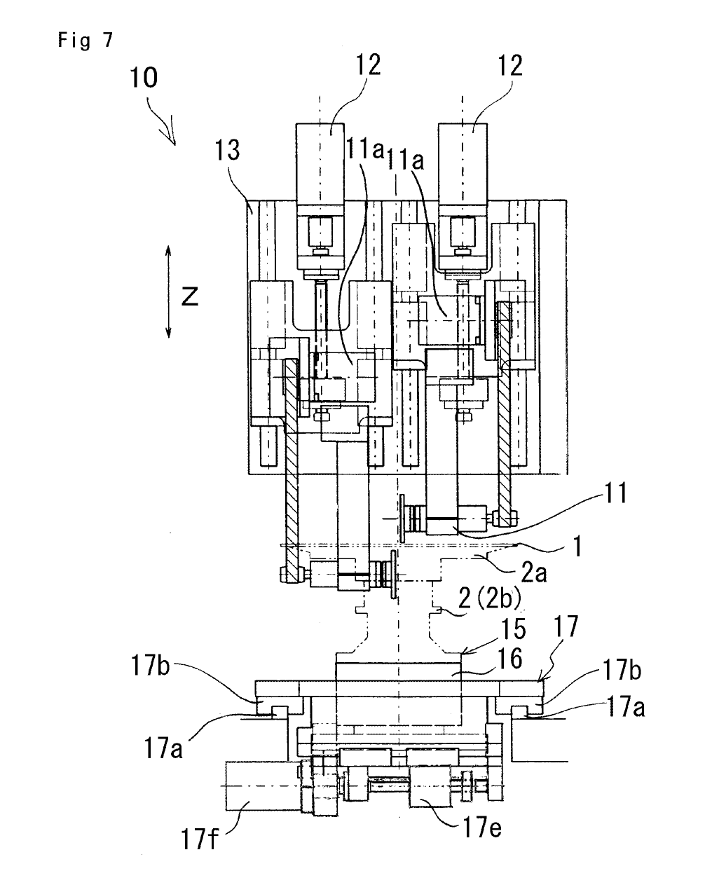

Next, a chamfering apparatus using the disk-like grooveless grindstones 3, 3 as shown in FIGS. 7 through 11 is described as an example of a chamfering apparatus that can be used in the chamfering method of the present invention.

A chamfering apparatus 10 positions the two disk-like grooveless grindstones 3, 3, with the side faces facing each other being located in the vicinity of each other, and uses the circumferential faces as the processing faces. The chamfering apparatus 10 can set the straight line passing through the center of the wafer 1 and the centers in the positions of the two disk-like grooveless grindstones 3, 3 in the middle positions between the points of contact of the two grindstones 3, 3 with the wafer 1. In this manner, the chamfering apparatus 10 can perform bilaterally symmetrical grinding and polishing.

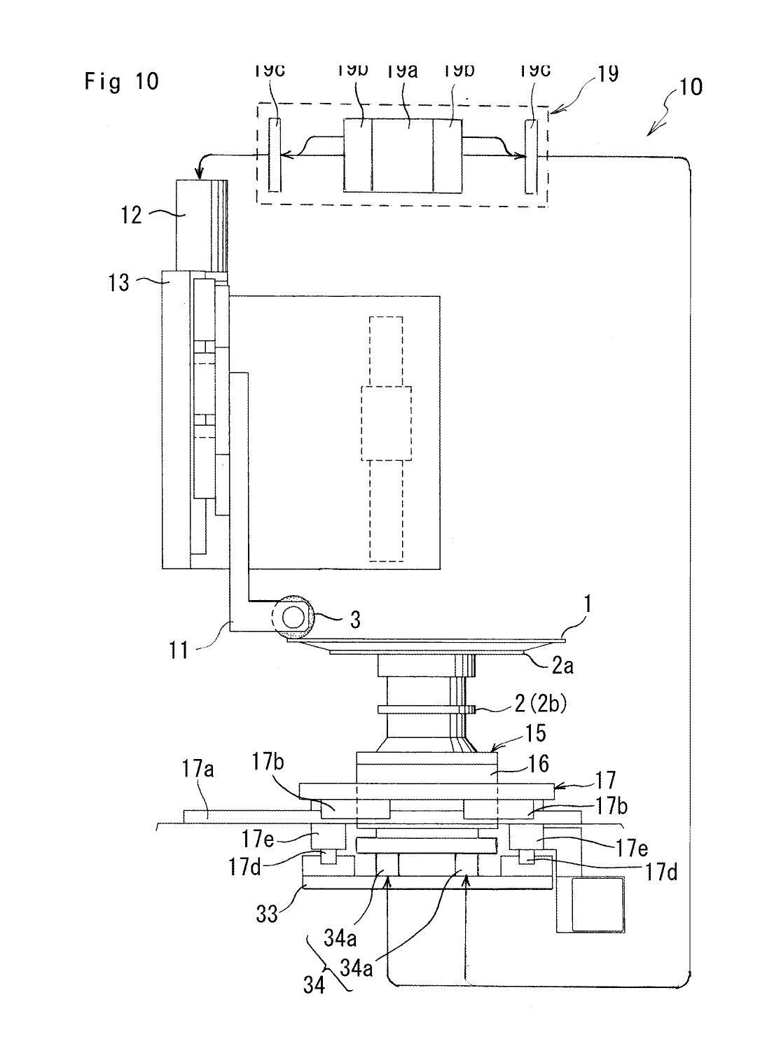

The respective disk-like grooveless grindstones 3, 3 are supported by grindstone supporting devices 11, 11 having grindstone drive devices 11a, 11a, and the grindstone supporting devices 11, 11 are supported in a vertically (Z-direction) movable manner by grindstone elevating devices 12, 12 (equipped with precision grinding Z-axis motors). Further, each of the grindstone elevating devices 12, 12 certainly secures a securing side member to a base 13 without a deviation from the mark, and supports a movement side member in a vertically (Z-direction) movable manner (FIGS. 7, 10).

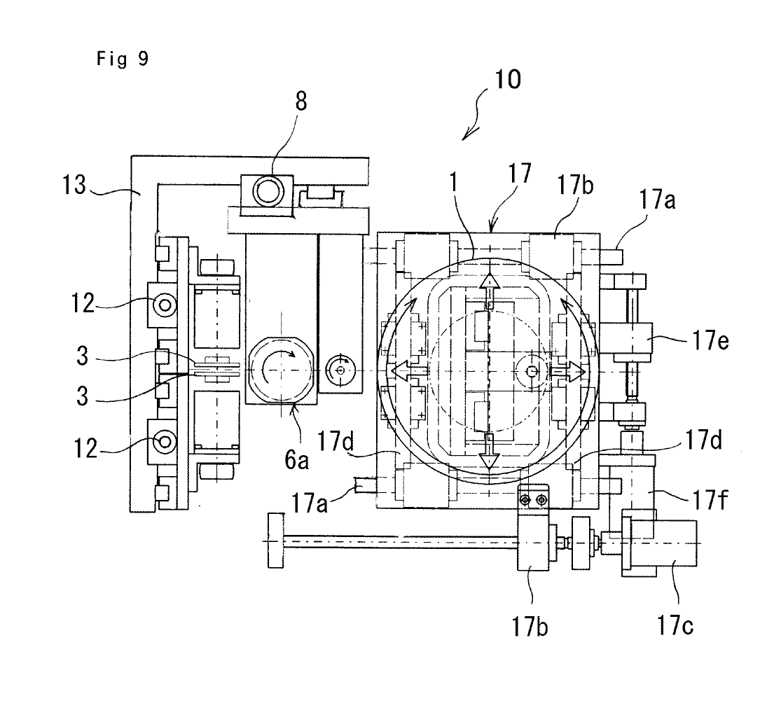

A work supporting device 15 includes: a pedestal 16 on which the rotary table 2a having the wafer 1 mounted thereon and the work table 2 including a work mounting table rotating device 2b (equipped with a θ-axis motor) for rotating the rotary table 2a are mounted; amount 17 that supports the pedestal 16; depth-direction moving bodies 17b, 17b that are placed on rails 17a, 17a provided for linearly moving the mount 17 in the depth direction (Y-direction) and are to be linearly moved in the depth direction, and a depth-direction moving device 17c (equipped with a Y-axis motor) serving as the drive device for the depth-direction moving bodies 17b, 17b; horizontal-direction moving bodies 17e, 17e that are placed on rails 17d, 17d provided for linearly moving the rails 17a, 17a, the depth-direction moving bodies 17b, 17b, and the depth-direction moving device 17c in the horizontal direction (the X-direction), and are to be linearly moved in the horizontal direction, and a horizontal-direction moving device 17f (equipped with an X-axis motor) serving as the drive device for the horizontal-direction moving bodies 17e, 17e, with the rails 17a, 17a, the depth-direction moving bodies 17b, 17b, and the depth-direction moving device 17c being placed on the rails 17d, 17d. The work supporting device 15 rotates the wafer 1, and can move and chamfer the wafer 1 to the positions in which the two disk-like grooveless grindstones 3, 3 are provided (FIGS. 9, 10).

Even if displacement occurs in the wafer 1 due to deformation, vibration, flipping, or the like in the vertical direction at the time of chamfering by the chamfering apparatus 10, processing is performed so that relative misalignment does not occur with the movement of the disk-like grooveless grindstones 3, 3. Therefore, a wafer-side elevating device 34 that includes (wafer-side elevating Z-axis) piezoelectric actuators 34a, . . . , 34a and moves the pedestal 16 and components mounted thereon in the vertical direction, with a wafer-side elevating device supporting member 33 being the reference position, is interposed between the lower end face of the pedestal 16 and the wafer-side elevating device supporting member 33 in the middle positions between the respective rails 17a, 17a and between the respective rails 17d, 17d.

Control devices for controlling operations of the grindstones 3, 3, the grindstone drive devices 11a, 11a, the elevating devices 12, 12, 34, the moving devices 17c, 17f, and the like at the time of processing input initial value settings and the like through an operation panel 19a provided in a control box 19, as shown by the control system chart in FIG. 10. The control devices transmit control signals as operation instructions to the grindstone elevating devices 12, 12, the wafer-side elevating device 34, the work table 2 including the work mounting table rotating device 2b rotating the rotary table 2a, the mount 17 having the depth-direction moving device 17c and the horizontal-direction moving device 17f provided thereon, and the like, which include respective controllers provided in the processing apparatus main frame. The control signals are output from a controller 19b using a control apparatus such as a microcomputer or a personal computer, via a control signal output unit 19c, so that chamfering operations are controlled based on the initial value settings.

The control box 19 includes: the operation panel 19a that includes a liquid crystal monitor, a keyboard, a PBS, and the like, sets initial conditions necessary for the operation of each control device through the input unit, issues instructions as to processing operations to be performed according to necessary control procedures, and enables monitoring of the conditions necessary for chamfering such as the setting conditions, processing conditions, initial states, and operating conditions, and of the statuses of the respective devices; the controller 19b that sets the operating conditions for the grindstone drive devices 11a, 11a rotating the respective disk-like grooveless grindstones 3, 3, the grindstone elevating devices 12, 12, the wafer-side elevating device 34, the work table 2 including the work mounting table rotating device 2b, the mount 17 having the depth-direction moving device 17c and the horizontal-direction moving device 17f provided thereon, and the like in accordance with the designated setting conditions, and sets the control signals to be transmitted; and the control signal output unit 19c that receives the signals output from the controller 19b, and transmits the control signals necessary for performing designated operations.

As shown in FIG. 11, each of the control devices includes: a wafer setting control device 9a that actuates a robot Z-axis motor, an absorption arm R-axis motor, or a loader actuator to move the wafer 1 from a stand-by position onto the rotary table 2a, actuates alignment (θ-axis, Y-axis) motors to make the eccentricity clear, matches axial centers to each other by correcting the eccentricity, positions the wafer 1 by moving the rotary table 2a to the processing position, determines the initial processing position based on the position of the notch in, and transfers the finished wafer 1 rotated at a high speed for finishing the outer circumferential end where necessary and cleaning the surface after the processing, to the collecting site for processed wafers 1; a wafer processing control device 9b that unites control devices that control operating directions such as the wafer rotating direction, the horizontal direction (the X-axis direction), the depth direction (the Y-axis direction), and the finishing vertical direction (the Z-axis direction) independently of one another; a wafer crude-processing control device 9c that unites the devices (such as a crude-grinding profile grindstone motor 6a and a crude-grinding stick-like grindstone motor 7a) that are to be controlled and are provided in a grindstone vertical-direction moving device 8 (equipped with a crude-grinding Z-axis motor) added for crude processing to be performed prior to the precision processing of the wafer 1; and a notch precision-processing control device 9d that unites the control devices for the respective drive devices for precision-processing the notch 1n that determines the reference position on the circumference of the wafer 1.

Those control devices 9a through 9d are controlled based on the control signals output from the control signal output unit 19c, to activate necessary drive devices W. Each of the drive devices W is controlled to operate in harmony with the other drive devices.

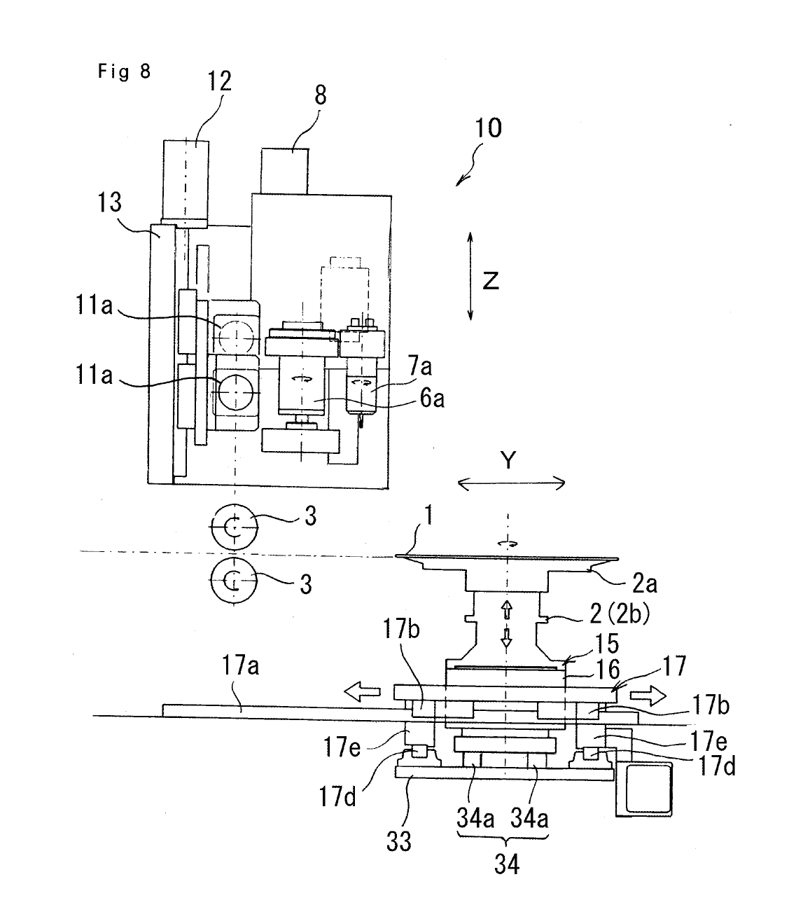

When chamfering is performed on a wafer 1 with the use of the chamfering apparatus 10, the wafer setting control device 9a is first driven from the controller 19b via the control signal output unit 19c. One wafer 1 is pulled out from wafers 1 stacked on one another or wafers 1, . . . , 1 stored in a cassette, and is transferred onto the rotary table 2a. The depth-direction moving device (the Y-axis motor) 17c is further driven by a control signal output from the control signal output unit 19c in accordance with an instruction from the controller 19b, to transfer the rotary table 2a having the wafer 1 placed thereon from the wafer preparation position shown in FIGS. 8 and 9 to the wafer processing position shown in FIGS. 7 and 10. After the transfer, the circumferential end diameter is reduced.

In reducing the circumferential end diameter, the two grindstone elevating devices 12, 12 (equipped with precision-grinding Z-axis motors) are driven by a control signal output from the control signal output unit 19c in accordance with an instruction from the controller 19b, and the respective disk-like grooveless grindstones 3, 3 are positioned with respect to the wafer 1 as shown in FIG. 2 or 3, depending on the shape of the circumferential end to be formed. The work mounting table rotating device 2b (equipped with a 0-axis motor) of the wafer processing control device 9b and the grindstone drive devices 11a, 11a (equipped with precision-grinding spindle motors) for the respective disk-like grooveless grindstones 3 are activated. The rotation of each of the disk-like grooveless grindstones 3, 3 is adjusted to the number of rotations at the time of the circumferential end diameter reduction, and the rotation of the wafer 1 and the rotation of the disk-like grooveless grindstones 3, 3 are appropriately controlled, to perform grinding with high precision. When the diameter approaches the required diameter, the operation is switched to a precision-polishing operation (sparkout), and processing is performed so that the wafer diameter at the edge 1a of the wafer 1 matches the desired shape.

A contouring process is then performed.

In the contouring process, the upper and lower faces of the wafer 1 are sandwiched by the respective disk-like grooveless grindstones 3, 3 as shown in FIGS. 4 and 5, and processing is performed while the relative positions of the upper and lower disk-like grooveless grindstones 3, 3 are adjusted independently of each other.

In adjusting the relative positions, the operation of the grindstone elevating device (the precision-grinding upper grindstone Z-axis motor) 12 for the upper grindstone for precision processing is adjusted by a precision-processing upper grindstone Z-axis control signal that is output from the control signal output unit 19c. At the same time, the operation of the grindstone elevating device (the precision-grinding lower grindstone Z-axis motor) 12 for the lower grindstone for precision processing is adjusted by a precision-processing lower grindstone Z-axis control signal that is output from the control signal output unit 19c. In this manner, misalignment due to deformation, vibration, flipping, or the like of the wafer 1 is restrained by the respective disk-like grooveless grindstones 3, 3, and the positions of the respective disk-like grooveless grindstones 3, 3 in the Z-axis direction are adjusted, to facilitate the contouring process while correcting the positions of the upper and lower faces independently of each other. Further, at the same time as above, the elevating operation by the wafer-side elevating device 34 is adjusted by a wafer-side elevating Z-axis control signal that is output from the control signal output unit 19c, so that the upper and lower relative positions of the upper and lower disk-like grooveless grindstones 3, 3 with respect to the wafer 1 are maintained in predetermined positions. Also, the rotation of each of the disk-like grooveless grindstones 3, 3 at the time of processing is adjusted to the number of rotations at the time of the contouring process, so that the rotation of the wafer 1 and the rotation of the disk-like grooveless grindstones 3, 3 are appropriately controlled to form the edge shape with high precision. When the edge shape becomes almost the required shape, the operation is switched to a precision-polishing operation (sparkout), and polishing is performed to match the shape of the edge 1a of the wafer 1 to the size of the desired shape. In this manner, the precision in the processed shape is improved.

### First Embodiment

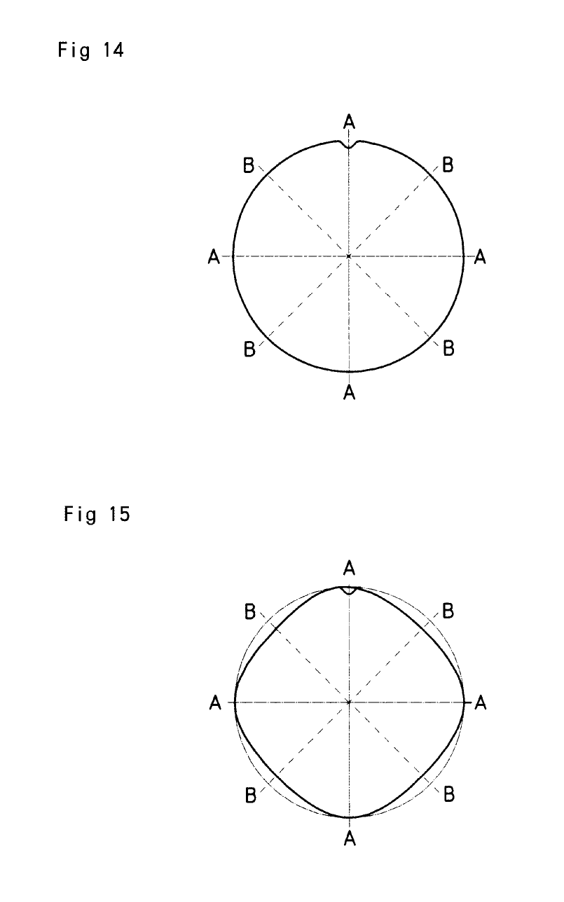

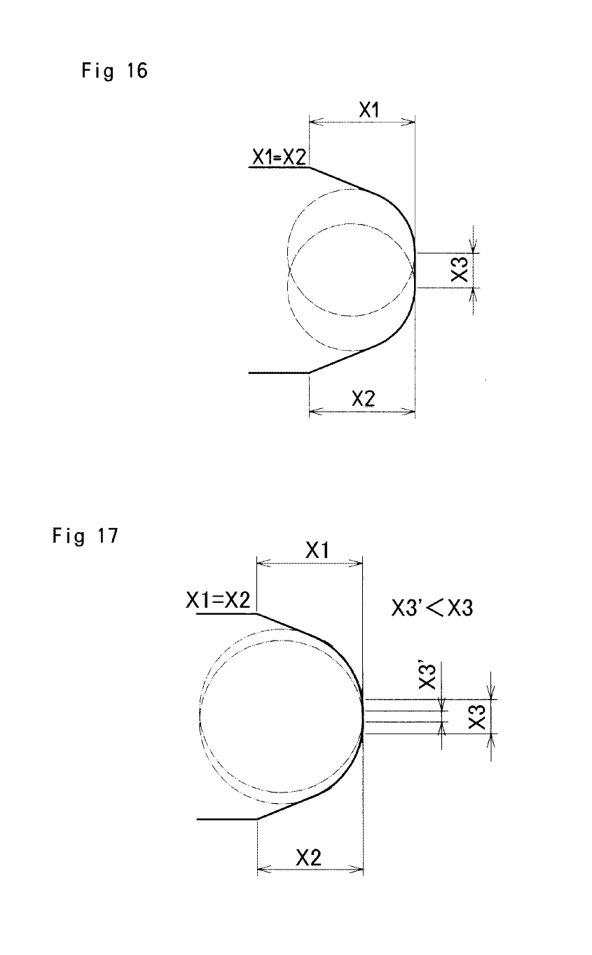

By the wafer chamfering method of the present invention, the processing apparatus 10 described above as an example performs centering of the wafer 1, places the wafer 1 onto the rotary table 2a, rotates the wafer 1, brings the grooveless grindstone 3 for processing the rotating wafer 1 into contact with the wafer circumferential end portion 1a, and then performs a chamfering operation to chamfer the wafer 1. In the present invention, particularly when the same cross-sectional shape is formed on the entire wafer circumference (FIGS. 14, 16), the movement trajectories of the wafer 1 and the grindstones 3 are set as references, and the relative positions of the wafer 1 and the grindstone 3 are moved from the above reference trajectory positions at least in one of the Z-axis and Y-axis directions, depending on wafer rotation angle positions. The piezoelectric actuators 34a are used to perform the processing operation to form cross-sectional shapes that vary with the rotation angle positions of the wafer 1.

Here, the references described above are data about the movement trajectories obtained when the wafer 1 and the grindstones 3 are moved in a relative manner in the Z-axis and Y-axis directions in a case where the same cross-sectional shape is formed on the entire wafer circumference.

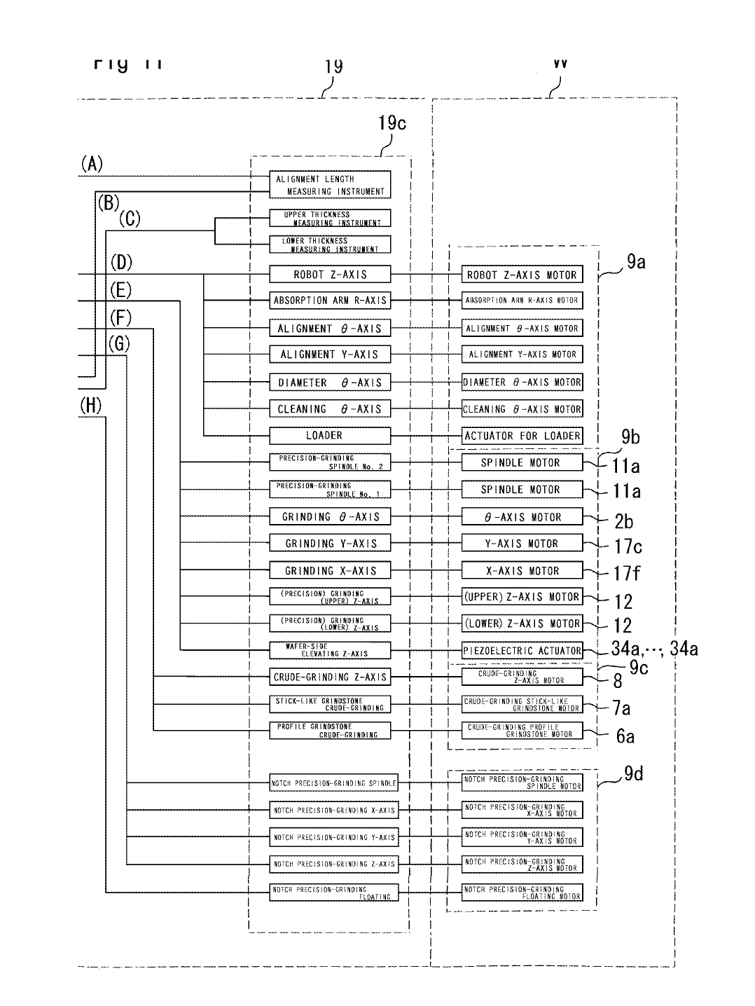

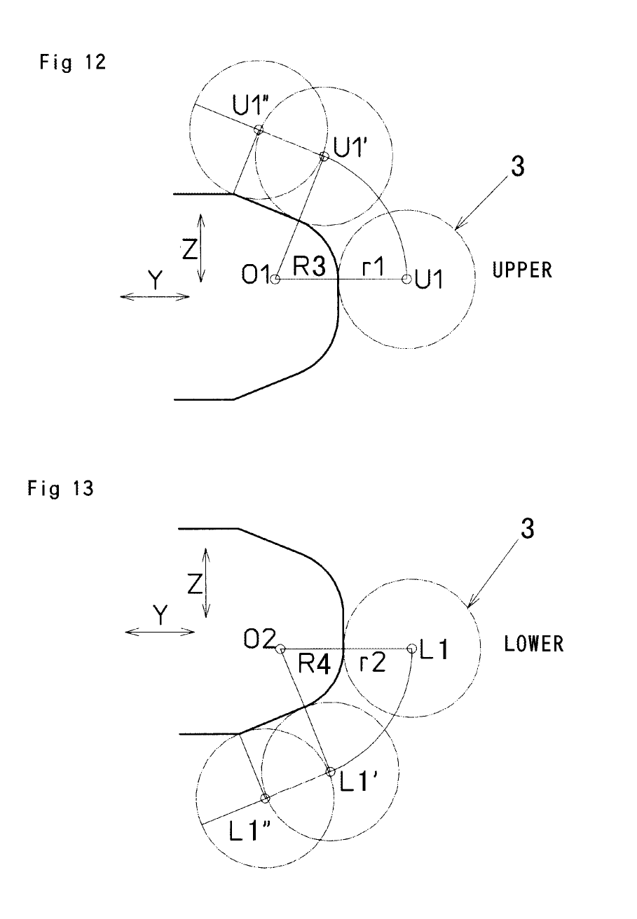

FIG. 12 shows the relative reference trajectory of the grindstone 3 processing the upper face side in a wafer cross-section. FIG. 13 shows the relative reference trajectory of the grindstone 3 processing the lower face side in a wafer cross-section.

In the processing of the upper face side, the grindstone 3 is first moved in an ark-like manner from a curved-face start position (U1) of the circumferential end 1b, with the center being O1, the radius being R3+r1. When reaching the upper-slope start position U1′, the grindstone 3 is obliquely moved in a parallel manner to U1″, to form the upper slope 1au.

Likewise, in the processing of the lower face side, the grindstone 3 is first moved in an ark-like manner from a curved-face start position (L1) of the circumferential end 1b, with the center being O2, the radius being R4+r2. When reaching the upper-slope start position L1′, the grindstone 3 is obliquely moved in a parallel manner to L1″, to form the lower slope 1ad.

FIG. 10 shows an example in which the piezoelectric actuators 34a are provided on the wafer-side elevating Z-axis, and, particularly in the wafer chamfering process of the present invention in which the cross-sectional shape varies with the rotation angle positions of the wafer 1 rotating at a high speed, the processing can be accurately followed.

To maintain the symmetric properties of the cross-sectional shape in the thickness direction, the processing of the cross-sectional shape on the upper face side is performed separately from the processing of the cross-sectional shape on the lower face side in the case where the piezoelectric actuators 34a are provided on the wafer-side elevating Z-axis. In cases where the piezoelectric actuators are provided on the wafer-side horizontal Y-axis or on the grindstone-side elevating Z-axis, the processing of the cross-sectional shape on the upper face side and the processing of the cross-sectional shape on the lower face side can be performed at the same time.

As shown in FIG. 12, the rotation angle positions of the wafer 1 are defined by dividing the center angle of the wafer 1 into eight, and the relative positional relationship between the grindstones 3 and the wafer 1 is alternately changed at every 45 degrees in rotation angle of the wafer 1. In this manner, two different cross-sectional shapes can be formed.

In rotation angle positions between changes in the relative positional relationship between the grindstones 3 and the wafer 1 at every 45 degrees in the rotation angle of the wafer 1, the wafer shape is continuously changed. In this manner, a continuous change is repeated. The continuous shape is formed with curves such as a spline curve, a hyperbolic curve, a sine curve, or an elliptical arc, and may partially include a straight line.

The cross-sectional shapes obtained by alternately changing the relative positional relationship between the grindstones and the wafer at every 45 degrees in the rotation angle of the wafer 1 in this embodiment can be the following shapes.

In a first cross-sectional shape, two different wafer radiuses are formed, depending on the rotation angle positions of the wafer.

In this case, the relative positions of the wafer 1 and the grindstones 3 are changed from the above described reference trajectory positions in the Y-axis (in combination of the Z-axis where necessary) at every 45 degrees in the wafer rotation angle, to form different cross-sectional shapes (A, B) in accordance with the rotation angle positions of the wafer.

As a result, the wafer 1 has the planar shape shown in

FIG. 15, for example, with the radius being changed at every 45 degrees in rotation angle, In FIG. 15, the differences in wafer radius are exaggerated, compared with the situation of FIG. 14 without any such radius change, and the actual differences are in the range of approximately 5 to 50 microns.

In this case, it is also preferable to continuously change the wafer radius in the rotation angle positions between the changes in the relative positional relationship between the grindstones 3 and the wafer 1 at every 45 degrees in rotation angle of the wafer 1. Such a continuous shape is formed with curves such as a spilne curve, a hyperbolic curve, a sine curve, or an elliptical arc, and may include a straight line.

In a second cross-sectional shape, the radius of the circular arcs at the wafer edge are varied while the chamfer widths X1 and X2 of the wafer edge, slopes are fixed.

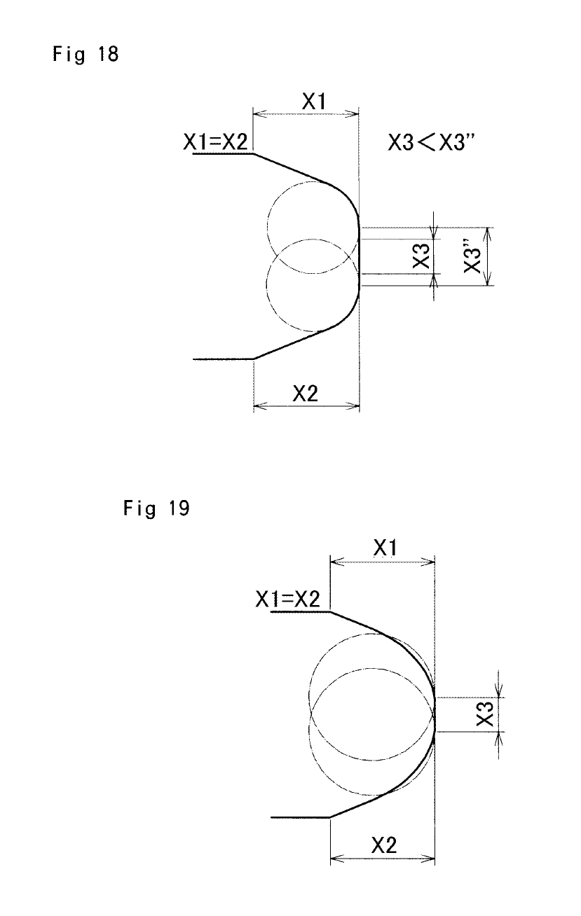

That is, the circular arcs at the wafer edge shown by solid lines in FIGS. 17 and 18 have different radiuses, compared with the reference cross-sectional shape shown in FIG. 16.

In a third cross-sectional shape, the curves at the wafer edge are varied while the chamfer widths X1 and X2 of the wafer edge slopes and the length X3 of the straight line at the wafer edge portion are fixed.

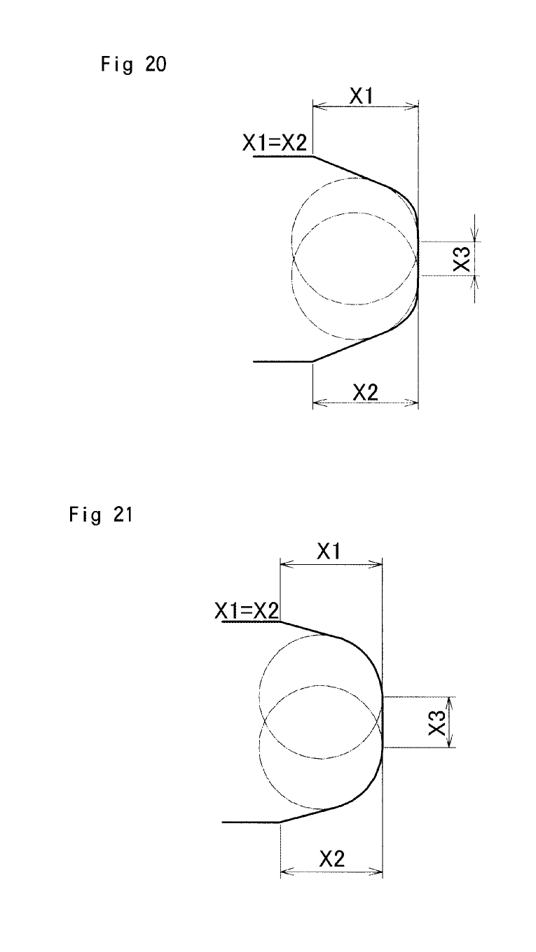

As opposed to FIG. 16, FIGS. 19 and 20 show situations where the curves at the wafer edge are varied while the chamfer widths X1 and X2 and the length X3 of the straight line at the wafer edge portion are fixed. The curve may be a spline curve, a hyperbolic curve, a sine curve, an elliptical arc, or the like.

In a fourth cross-sectional shape, the angles of the wafer edge slopes are varied while the chamfer widths X1 and X2 of the wafer edge slopes are fixed.

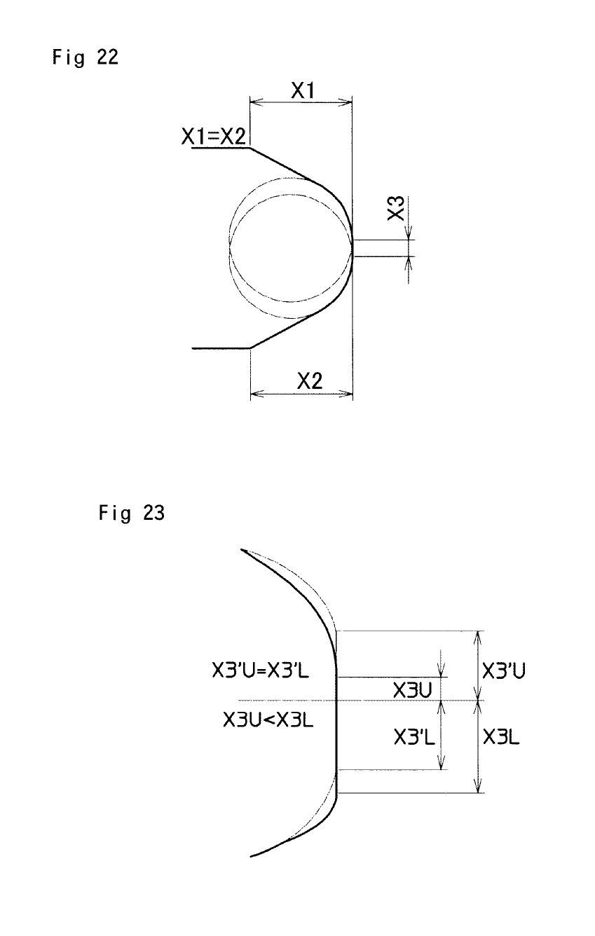

As opposed to FIG. 16 without variations of angles of the wafer edge slopes, FIGS. 21 and 22 show situations where the angles of the wafer edge slopes are varied, and the face width X3 at the circumferential end 1b is also varied.

In the present invention, when the chamfering method for forming the above described different cross-sectional shapes depending on the rotation angle positions of the wafer 1 is implemented, the wafer 1 and the grindstones 3 are moved in a relative manner in the Z-axis and Y-axis directions, and the grindstones 3 are brought into contact with the wafer 1, to form a desired cross-sectional shape at the wafer edge. In doing so, the circular-arc or curved-line start positions adjacent to the straight line portion at the wafer edge are deviated from the trajectories of the grindstones 3 and the wafer 1 by a predetermined amount, and, as the wafer edge becomes further away, the processing gradually returns to the original circular-arc or curved-line trajectories. In this manner, wafer chamfering can also be performed.

Also, in the present invention, when the chamfering method for forming the above described different cross-sectional shapes depending on the rotation angle positions of the wafer 1 is implemented, the wafer 1 and the grindstones 3 are first moved in a relative manner in the Z-axis and Y-axis directions, to form a desired cross-sectional shape at the wafer edge. In a later stage, the grindstones 3 are again brought into contact with the straight line portion at the wafer edge, and are moved in a relative manner in the Z-axis and Y-axis directions. The straight line portion at the wafer edge is then tilted at a predetermined angle with respect to the original straight line. In this manner, wafer chamfering can also be performed.

### Second Embodiment

By a wafer chamfering method of the present invention illustrated as a second embodiment in FIG. 23, the above described processing apparatus 10 performs centering of a wafer 1, and places the wafer 1 onto the rotary table 2a. The wafer 1 is rotated, and the grooveless grindstones 3 are brought into contact with the wafer circumferential end portion 1a, to chamfer the wafer 1. In doing so, the circular-arc or curved-line start positions adjacent to, the straight line portion at the wafer edge are deviated by a predetermined amount from the trajectories (indicated by alternate long and two short dashes lines) formed by moving the wafer 1 and the grindstones 3 in a relative manner in the Z-axis and Y-axis directions and bringing the grindstones 3 into contact with the wafer 1 so as to form the same cross-sectional shape at the edge on the entire wafer circumference. As the wafer edge becomes further away, the processing gradually returns to the original circular-arc or curved-line trajectories (indicated by solid lines). In this manner, the same cross-sectional shape is formed at the edge of the entire wafer circumference.

By forming a cross-sectional shape that is vertically asymmetrical (X3U<X3L) with deformation being taken into account in the chamfering step, a cross-sectional shape (indicated by alternate long and two short dashes lines) that becomes vertically symmetrical (X3′U=X3′L) after the chamfering step can be obtained.

### Third Embodiment

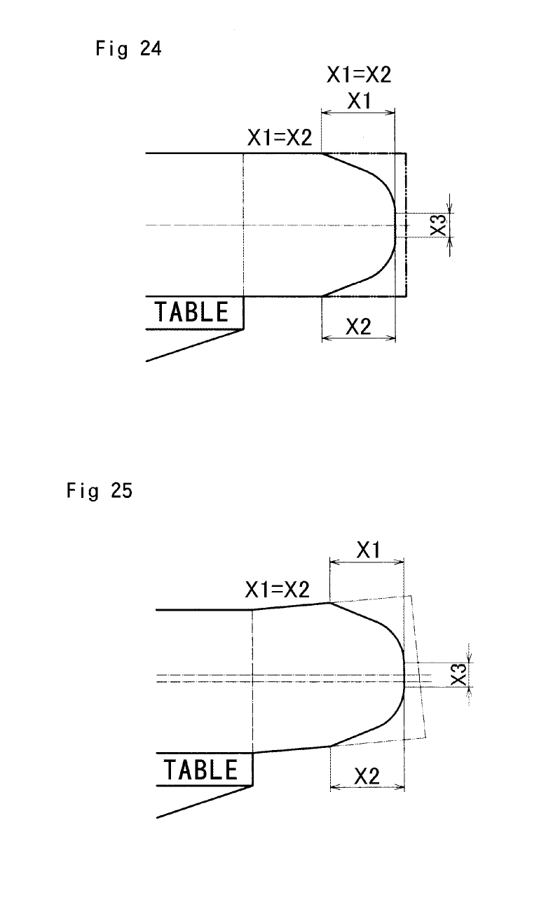

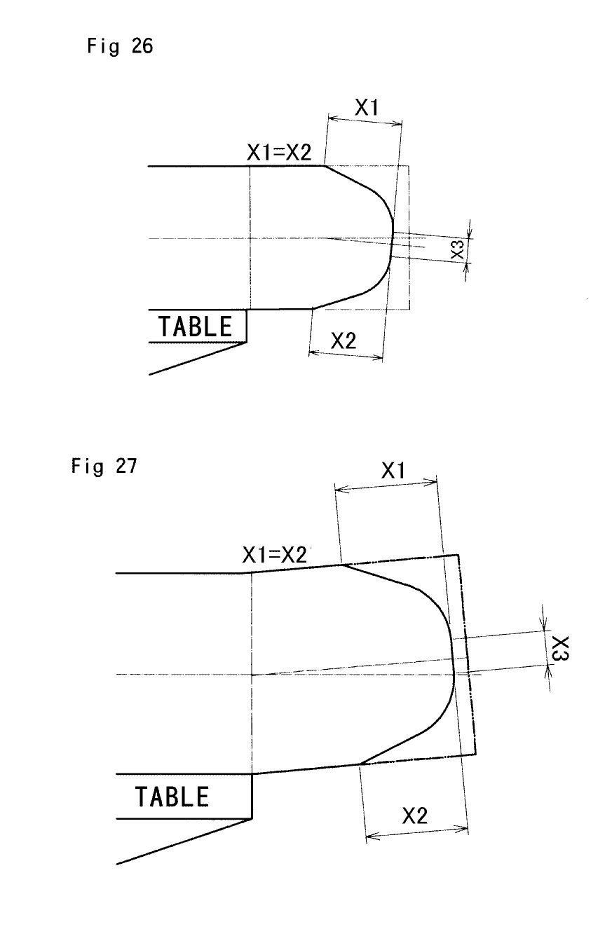

Even when the normal cross-sectional shape shown in FIG. 24 is to be formed, the wafer 1 is deformed by the pressure from the grindstones 3 during the chamfering step as shown in FIG. 25. If processing is performed perpendicularly to the straight line portion (the circumferential end 1b) at the wafer edge in this situation, the cross-sectional shape becomes asymmetrical as shown in FIG. 26 when the straight line portion at the wafer edge returns to the original state after the chamfering step, and a normal cross-sectional shape cannot be obtained.

Therefore, in a third embodiment, the above described processing apparatus 10 performs centering of a wafer 1, and places the wafer 1 onto the rotary table 2a. The wafer 1 is rotated, and the grooveless grindstones 3 are brought into contact with the wafer circumferential end portion 1a, to chamfer the wafer 1. In doing so, the wafer 1 and the grindstones 3 are moved in a relative manner in the Z-axis and Y-axis directions, to form a desired cross-sectional shape at the wafer edge. In the later chamfering step, the grindstones 3 are again brought into contact with the straight line portion at the wafer edge and are moved in a relative manner in the Z-axis and Y-axis directions, and the straight line portion at the wafer edge is tilted at a predetermined angle with respect to the original straight line, as shown in FIG. 27.

Processing is performed by tilting the straight line portion (the circumferential end 1b) at the wafer edge at a predetermined angle with respect to the original (vertical) straight line, with deformation during the chamfering step being taken into account. In this manner, a cross-sectional shape that becomes vertically symmetrical (FIG. 24) after the chamfering step can be obtained.

### Fourth Embodiment

By a wafer chamfering method as a fourth embodiment of the present invention, the various cross-sections of a wafer are measured in projected images in each of the above described embodiments, and the movements of the grindstones and the wafer in the Z-axis and Y-axis directions are determined so that the wafer edge has a desired cross-sectional shape.

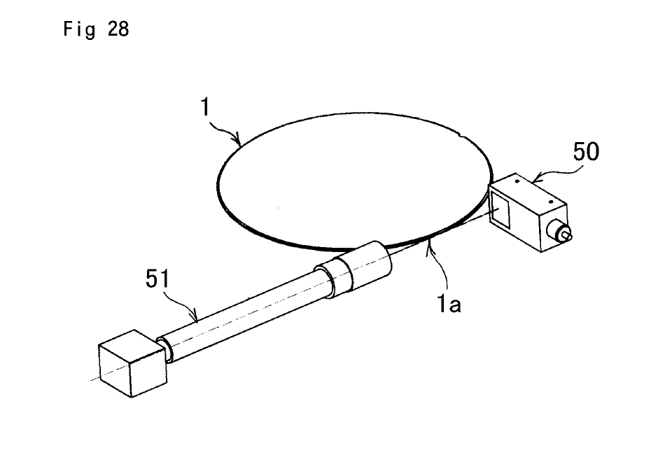

To obtain the projected images, as shown in FIG. 28, parallel light is emitted from an illuminator 50 to a point near the edge 1a of a rotating wafer 1, and a CCD camera 51 receives the light, to obtain information for forming a desired cross-sectional shape on the entire circumference of the wafer 1. In this manner, the movements of the grindstones 3 and the wafer 1 in the Z-axis and Y-axis directions are determined.

### DESCRIPTION OF REFERENCE SYMBOLS

1 wafer
1a edge (circumferential end portion)
1au upper slope
1ad lower slope
1b circumferential end
1c circular arc
1d oblique grinding mark
1e (opposite) oblique grinding mark
1n notch
2 work table
2a rotary table
2b work mounting table rotating device (with θ-axis motor)
3 disk-like grooveless grindstone
8 grindstone vertical-direction moving device (with crude-grinding Z-axis motor)
9a wafer setting control device
9b wafer processing control device
9c wafer crude-processing control device
9d notch precision-processing control device
10 chamfering apparatus
11 grindstone supporting device
11a grindstone drive device (with precision-grinding spindle motor)
12 grindstone elevating device (with precision-grinding Z-axis motor)
13 base
15 work supporting device
16 pedestal
17 mount
17a, 17d rail
17b depth-direction (Y-direction) moving body
17c depth-direction moving device (with Y-axis motor)
17e horizontal-direction (X-direction) moving body
17f horizontal-direction moving device (with X-axis motor)
19 control box
19a operation panel
19b controller
19c control signal output unit
33 wafer-side elevating device supporting member
34 wafer-side elevating device
34a piezoelectric actuator (in wafer-side elevating Z-axis)
50 illuminator
51 CCD camera
R1, R2, R3, R4, r1, r2 radius
W drive device
X1, X2, X3 chamfer width
X, Y, Z, θ arrow (indicative of moving direction)
α1, α2 angle
O1, O2 center
U1, L1 trajectory

1. A wafer chamfering method for chamfering a wafer by performing centering of a wafer, placing the wafer on a rotary table, rotating the wafer, and bringing a grooveless grindstone into contact with a wafer circumferential end portion, the grooveless grindstone being for processing the rotating wafer,
the wafer chamfering method comprising:
setting a reference movement trajectory that is formed by moving the wafer and the grindstone in a relative manner in Z-axis and Y-axis directions, and forming the same cross-sectional shape on an entire wafer circumference; and
forming different cross-sectional shapes depending on wafer rotation angle positions with the use of a piezoelectric actuator, so as to perform a processing operation in which relative positions of the wafer and the grindstone are changed from positions on the reference trajectory in at least one of the Z-axis and Y-axis directions, depending on the wafer rotation angle positions.

2. The wafer chamfering method according to claim 1, wherein a relative positional relationship between the grindstone and the wafer is alternately changed at every 45 degrees in rotation angle of the wafer, to form two different cross-sectional shapes.

3. The wafer chamfering method according to claim 2, wherein a wafer cross-sectional shape is continuously varied in rotation angle positions between changes in the relative positional relationship between the grindstone and the wafer at every 45 degrees in rotation angle of the wafer.

4. The wafer chamfering method according to claim 1, wherein a relative positional relationship between the grindstone and the wafer is alternately changed at every 45 degrees in rotation angle of the wafer, to form two different wafer radiuses.

5. The wafer chamfering method according to claim 4, wherein a wafer radius is continuously varied in rotation angle positions between changes in the relative positional relationship between the grindstone and the wafer at every 45 degrees in rotation angle of the wafer.

6. The wafer chamfering method according to claim 2 or 3, wherein the two cross-sectional shapes have different circular arc sizes at a wafer edge while maintaining the same chamfer width of a wafer edge slope.

7. The wafer chamfering method according to claim 2 or 3, wherein the two cross-sectional shapes have different curved lines at a wafer edge while maintaining the same chamfer width of a wafer edge slope and the same straight line length at the wafer edge portion.

8. The wafer chamfering method according to claim 2 or 3, wherein the two cross-sectional shapes have a wafer edge slope at different angels while maintaining the same chamfer width of the wafer edge slope.

9. The wafer chamfering method according to claim 8, wherein
a trajectory is set by moving the wafer and the grindstone in a relative manner in the Z-axis and Y-axis directions, and bringing the grindstone into contact with the wafer to form a desired cross-sectional shape at a wafer edge,
a circular-arc or curved-line start position adjacent to a straight line portion at the wafer edge is deviated from the trajectory by a predetermined amount, and
processing is performed by gradually returning to an original circular-arc or curved-line trajectory as the wafer edge becomes further away.

10. The wafer chamfering method according to claim 9, wherein the amount of deviation of the circular-arc or curved-line start position adjacent to the straight line portion at the wafer edge varies with wafer rotation angles.

11. The wafer chamfering method according to claim 10, wherein,
after a desired cross-sectional shape is formed at a wafer edge by moving the wafer and the grindstone in a relative manner in the Z-axis and Y-axis directions,
the grindstone is again brought into contact with a straight line portion at the wafer edge, and is moved in a relative manner in the Z-axis and Y-axis directions, processing being performed by tilting the straight line portion at the wafer edge at a predetermined angle with respect to an original straight line.

12. A wafer chamfering method for chamfering a wafer by performing centering of a wafer, placing the wafer on a rotary table, rotating the wafer, and bringing a grooveless grindstone into contact with a wafer circumferential end portion, the grooveless grindstone being for processing the rotating wafer,
the wafer chamfering method comprising:
setting a trajectory by moving the wafer and the grindstone in a relative manner in Z-axis and Y-axis directions, and bringing the grindstone into contact with the wafer to form the same cross-sectional shape at an edge on an entire wafer circumference,
deviating a circular-arc or curved-line start position adjacent to a straight line portion at the wafer edge from the trajectory by a predetermined amount, and
performing processing by gradually returning to an original circular-arc or curved-line trajectory as the wafer edge becomes further away.

13. A wafer chamfering method for chamfering a wafer by performing centering of a wafer, placing the wafer on a rotary table, rotating the wafer, and bringing a grooveless grindstone into contact with a wafer circumferential end portion, the grooveless grindstone being for processing the rotating wafer,
the wafer chamfering method comprising:
forming the same cross-sectional shape at an edge on an entire wafer circumference by moving the wafer and the grindstone in a relative manner in Z-axis and Y-axis directions; and
performing processing by again bringing the grindstone into contact with a straight line portion at the wafer edge, moving the grindstone in a relative manner in the Z-axis and Y-axis directions, and tilting the straight line portion at the wafer edge at a predetermined angle with respect to an original straight line.

14. The wafer chamfering method according to claim 13, wherein a cross-section of the wafer is measured in a projected image, and movements of the grindstone and the wafer in the Z-axis and Y-axis directions are determined so that the wafer edge has a desired cross-sectional shape.
